(19) United States
(12) Patent Application Publication
(10) Pub. No.: US 2006/0068518 A1
(43) Pub. Date: Mar. 30, 2006

(54) Forming vertically aligned liquid crystal mixtures

(76) Inventor: Anna M. George, Sunnyvale, CA (US)

Correspondence Address: TROP PRUNER & HU, PC, 8554 KATY FREEWAY, SUITE 100, HOUSTON, TX, 77024, US

(21) Appl. No.: 10/954,048

(22) Filed: Sep. 29, 2004

(51) Int. Cl. H01L 21/00; G02F 1/1347

(52) U.S. Cl. 438/30

(57) ABSTRACT

Vertically aligned liquid crystal molecules may be formed using spin-on-glass deposition. After deposition, the molecules may be exposed to an oblique ion beam or e-beam bombardment. Other techniques for alignment involve microstructure formation such as using a double sided scrubber or high oxygen plasma processing. As a result, more conventional integrated circuit fabrication techniques may be utilized to form the vertically aligned liquid crystal layer giving higher reliability and a wider process window.

### BACKGROUND

This invention relates generally to the formation of liquid crystal over semiconductor integrated circuits.

In a liquid crystal over semiconductor integrated circuit, a layer of liquid crystal may be formed over a substrate. In display applications, higher contrast ratio may be achieved by vertically aligning the liquid crystal mixtures. In particular, the liquid crystal molecules may be aligned perpendicularly to the substrate, allowing them to achieve the targeted contrast ratio.

While techniques exist for achieving such vertical alignment, these techniques have a relatively narrow process window. These techniques may not be scalable to high volume manufacturing.

Thus, there is a need for better ways to form vertically aligned liquid crystal mixtures.

### BRIEF DESCRIPTION OF THE DRAWINGS

FIG. 1 is an enlarged, cross-sectional view of one embodiment of the present invention at an early stage of manufacture;

FIG. 2 is an enlarged, cross-sectional view of the embodiment shown in FIG. 1 at a subsequent stage of manufacture in accordance with one embodiment of the present invention;

FIG. 3 is an enlarged, cross-sectional view of the embodiment shown in FIG. 2 at a subsequent stage of manufacture in accordance with one embodiment of the present invention;

FIG. 4 is a cross-sectional view taken generally along the line 4-4 in FIG. 3 in accordance with one embodiment of the present invention;

FIG. 5 is a partial, greatly enlarged view of a portion of a display in accordance with one embodiment of the present invention; and

FIG. 6 is a schematic depiction of one embodiment of the present invention.

### DETAILED DESCRIPTION

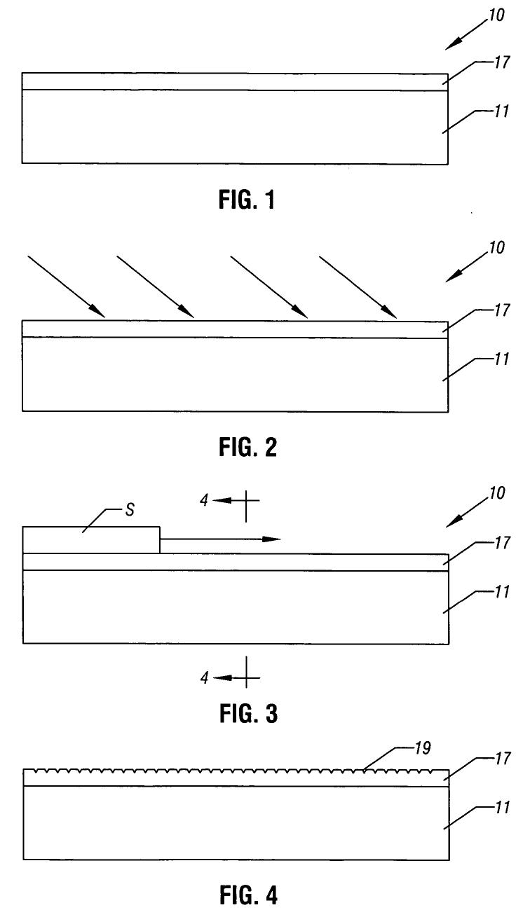

Referring to FIG. 1, a substrate 10 may be a semiconductor substrate such as a patterned silicon substrate. It may also be formed of a glass. A spin-on-glass alignment layer 17 is then formed over the substrate 11. The spin-on-glass may be an organic or non-organic layer. For example, the layer 17 may be formed of siloxane or methyl siloxane polymers dissolved in an organic solvent including ethyl alcohol, 2-propanol, acetone, n-butyl alcohol, or 2-methoxy-1-methyl ethyl acetate.

The layer 17 may be spun on the wafer using a conventional resist track. The layer 17 may then be treated to remove the solvent, cure the polymer, and densify the resulting film.

To this end, a variety of techniques may be utilized including hot plate, oven, furnace, ultraviolet, or e-beam techniques. In some embodiments, the layer 17 may have a thickness of from about 20 to 500 Angstroms.

Referring next to FIG. 2, an oblique ion beam or e-beam bombardment may be applied to the layer 17. This bombardment forms alignment microstructures.

It is also possible to use a scrubber S to scrub the exposed surface of the layer 17 to form alignment microstructures as shown in FIG. 3. For example, a double sided scrubber S may be utilized for this purpose. As a result of scrubbing, as shown in FIG. 4, microgrooves 19 may be formed in the layer 17. As another alternative, high oxygen plasma processing may also be utilized for microstructure formation.

Because the spin-on-glass process is a well developed, high volume manufacturing process, using equipment already available in integrated circuit fabrication techniques, it is a more reliable process with a wider process window compared to previous techniques for forming alignment layers.

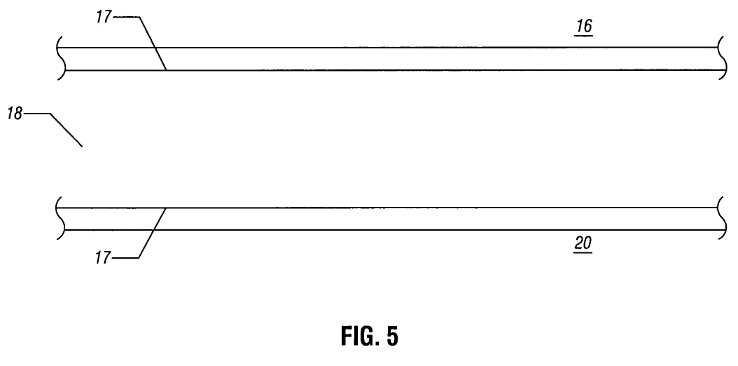

Referring to FIG. 5, alignment layer 17 may be positioned on both a top plate 16 and a substrate containing pixel electrodes 20. As a result, liquid crystal material 18 may be sandwiched in between, as shown in FIG. 5. The layer 17 may achieve alignment within about 6° degrees of vertical alignment.

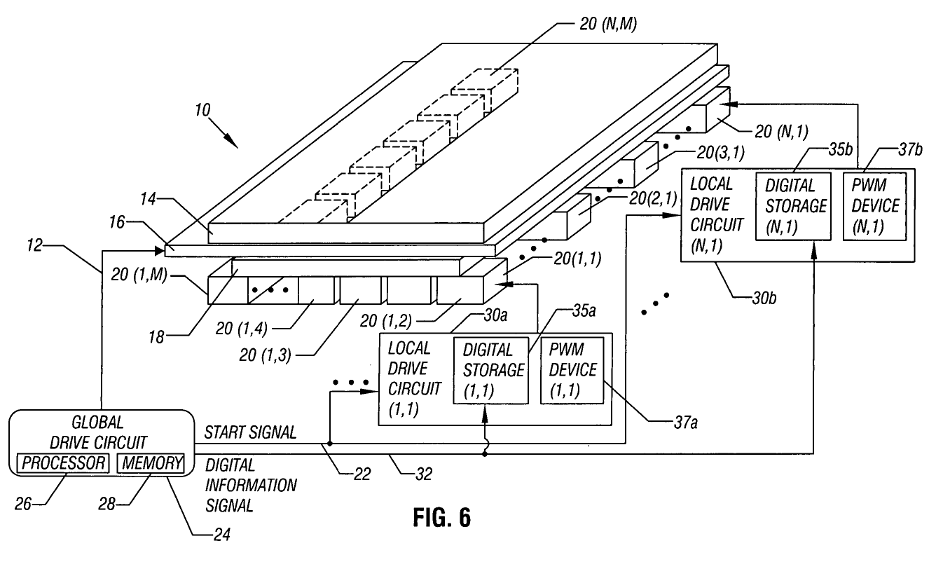

Referring now to FIG. 6, a display system 10 (e.g., a liquid crystal display (LCD), such as a spatial light modulator (SLM)) includes a liquid crystal layer 18 according to an embodiment of the present invention. In one embodiment, the liquid crystal layer 18 may be sandwiched between a transparent top plate 16 and a plurality of pixel electrodes 20(1, 1) through 20(N, M), forming a pixel array comprising a plurality of display elements (e.g., pixels). The layer 17 may be formed on the substrate that includes the electrodes 20, as well as on the bottom of the plate 16. This provides “over and under” anchoring of the liquid crystal layer 18. In some embodiments, the top plate 16 may be made of a transparent conducting layer, such as indium tin oxide (ITO). Applying voltages across the liquid crystal layer 18 through the top plate 16 and the plurality of pixel electrodes 20(1, 1) through 20(N, M) enables driving of the liquid crystal layer 18 to produce different levels of intensity on the optical outputs at the plurality of display elements, i.e., pixels, allowing the display on the display system 10 to be altered. A glass layer 14 may be applied over the top plate 16. In one embodiment, the top plate 16 may be fabricated directly onto the glass layer 14.

A global drive circuit 24 may include a processor 26 to drive the display system 10 and a memory 28 storing digital information including global digital information indicative of a common reference and local digital information indicative of an optical output from at least one display element, i.e., pixel. In some embodiments, the global drive circuit 24 applies bias potentials 12 to the top plate 16. Additionally, the global drive circuit 24 may provide a start signal 22 and a digital information signal 32 to a plurality of local drive circuits (1, 1) 30a through (N, 1) 30b, each of which may be associated with a different display element being formed by the corresponding pixel electrode of the plurality of pixel electrodes 20(1, 1) through 20(N, 1), respectively.

In one embodiment, a LCOS technology may be used to form the display elements of the pixel array. Liquid crystal devices formed using the LCOS technology may form large screen projection displays or smaller displays (using direct viewing rather then projection technology). Typically, the LC material is sandwiched between the thin alignment layers 17. A glass plate with an ITO layer covers the liquid crystal, creating the liquid crystal unit sometimes called a cell. A silicon substrate may define a large number of pixels. Each pixel may include semiconductor transistor circuitry in one embodiment. However, in other embodiments other digital modulation schemes and devices, for example, a digital light processor (DLP), such as a microelectromechanical systems (MEMS) device (e.g., a digital micromirror device) may be used.

One technique in accordance with an embodiment of the present invention involves controllably driving the display system 10 using pulse-width modulation (PWM). More particularly, for driving the plurality of pixel electrodes 20(1,1) through 20(N, M), each display element may be coupled to a different local drive circuit of the plurality of local drive circuits (1, 1) 30a through (N, 1) 30b, as an example. To hold and/or store any digital information intended for a particular display element, a plurality of digital storage (1, 1) 35a through (N, 1) 35b may be provided, each of which may be associated with a different local drive circuit of the plurality of local drive circuits (1, 1) 30a through (N, 1) 30b, for example. As discussed further below, such digital information may be used to determine a transition within a PWM waveform.

For generating a pulse-width modulated waveform based on the respective digital information, a plurality of PWM devices (1, 1) 37a through (N, 1) 37b may be provided in order to drive a corresponding display element. In one case, each PWM device of the plurality of PWM devices (1, 1) 37a through (N, 1) 37b may be associated with a different local drive circuit of the plurality of local drive circuits (1, 1) 30a through (N, 1) 30b.

Consistent with one embodiment of the present invention, the global drive circuit 24 may receive video data input and may scan the pixel array in a row-by-row manner to drive each pixel electrode of the plurality of pixel electrodes 20(1,1) through 20(N, M). Of course, the display system 10 may comprise any desired arrangement of one or more display elements. Examples of the display elements include spatial light modulator devices, emissive display elements, non-emissive display elements and current and/or voltage driven display elements.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming an alignment layer using a spin-on-glass technique; and
applying a liquid crystal layer in contact with said alignment layer.

2. The method of claim 1 including depositing an alignment layer on a substrate.

3. The method of claim 2 including forming said substrate with pixel electrodes.

4. The method of claim 1 including forming a liquid crystal over semiconductor integrated circuit.

5. The method of claim 4 including forming a projection display.

6. The method of claim 4 including forming an imager.

7. The method of claim 1 including forming said layer of a siloxane polymer.

8. The method of claim 1 including exposing said layer to an oblique beam bombardment.

9. The method of claim 1 including forming microgrooves in the surface of said alignment layer.

10. The method of claim 1 including scrubbing the surface of said alignment layer to form microgrooves therein.

11. The method of claim 1 including exposing said alignment layer to a plasma.

12. A liquid crystal over semiconductor integrated circuit comprising:
a liquid crystal layer; and
a pair of electrodes on either side of said liquid crystal layer, each of said electrodes including a spin-on glass alignment layer.

13. The integrated circuit of claim 12 wherein said integrated circuit is part of the projection display.

14. The integrated circuit of claim 12 wherein said integrated circuit is part of an imager.

15. The integrated circuit of claim 12 wherein in said spin-on glass includes siloxane polymer.

16. The integrated circuit of claim 12 wherein said spin-on glass is oblique beam bombarded.

17. The integrated circuit of claim 12 including microgrooves in the surface of at least one of said alignment layers.

18. A method comprising:
forming a set of electrodes in a substrate;
forming a spin-on-glass layer over said electrodes;
applying a liquid crystal layer in contact with said spin-on-glass layer; and
forming a cover over said liquid crystal layer.

19. The method of claim 18 including forming a spin-on-glass layer on said cover.

20. The method of claim 18 including depositing an alignment layer on a substrate.

21. The method of claim 19 including forming said substrate with pixel electrodes.

22. The method of claim 18 including forming a liquid crystal over semiconductor integrated circuit.

23. The method of claim 21 including forming a projection display.

24. The method of claim 21 including forming an imager.

25. The method of claim 18 including forming said layer of a siloxane polymer.

26. The method of claim 18 including exposing said layer to an oblique beam bombardment.

27. The method of claim 18 including forming microgrooves in the surface of said alignment layer.

28. The method of claim 18 including scrubbing the surface of said alignment layer to form microgrooves therein.

29. The method of claim 18 including exposing said alignment layer to a plasma.
